(19) United States
(12) Patent Application Publication
(10) Pub. No.: US 2009/0243694 A1
(43) Pub. Date: Oct. 1, 2009

(54) VOLTAGE CONVERTING DRIVER APPARATUS

(76) Inventors: Todd Mellinger, Fort Collins, CO (US); Charles Morganti, Fort Collins, CO (US); Stephen Maresh, Waltham, MA (US)

Correspondence Address: KED & ASSOCIATES, LLP;INTEL CORPORATION, P.O. BOX 221200, CHANTILLY, VA, 20153-1200, US

(21) Appl. No.: 12/059,806

(22) Filed: Mar. 31, 2008

(51) Int. Cl. H03L 5/00

(52) U.S. Cl. 327/333

(57) ABSTRACT

A voltage converting apparatus is provided that includes a dynamic driver circuit and a voltage converting circuit. The dynamic driver circuit may receive a clock signal and input signals and provide a dynamic signal based on the clock signal and the input signals. The voltage converting circuit may receive the dynamic signal from the dynamic driver circuit and provide an output signal based on the received dynamic signal. The dynamic driver circuit may be powered by a first voltage source and the voltage converting circuit may be powered by a second voltage source.

### FIELD

Embodiments of the present invention may relate to a voltage converting driver apparatus, such as a voltage converting driver for a memory array.

### BACKGROUND

In order to reduce power consumption, chips may be operated at lower voltages. However, a voltage supply of a memory array, such as a Static Random Access Memory (SRAM) array may be limited based on a size of the on-die memory (or cache). The voltage supply may be reduced by using a much larger (i.e., low density) memory cell. However, this may affect the ability to use larger memory (or cache) on die. On the other hand, the memory array may be supplied with a separate power supply and allow core logic to fall below a voltage supply minimum.

### BRIEF DESCRIPTION OF THE DRAWINGS

The foregoing and a better understanding of embodiments of the present invention may become apparent from the following detailed description of arrangements and example embodiments and the claims when read in connection with the accompanying drawings, all forming a part of the disclosure of this invention. While the foregoing and following written and illustrated disclosure focuses on disclosing arrangements and example embodiments of the invention, it should be clearly understood that the same is by way of illustration and example only and the invention is not limited thereto.

The following represents brief descriptions of the drawings in which like reference numerals represent like elements and wherein:

FIG. 1 shows a memory interface and a portion of a memory array according to an example arrangement;

FIG. 2 shows a voltage converting driver apparatus according to an example embodiment of the present invention;

FIG. 3 shows a voltage converting driver apparatus according to an example embodiment of the present invention;

FIG. 4 shows an apparatus according to an example embodiment of the present invention.

### DETAILED DESCRIPTION

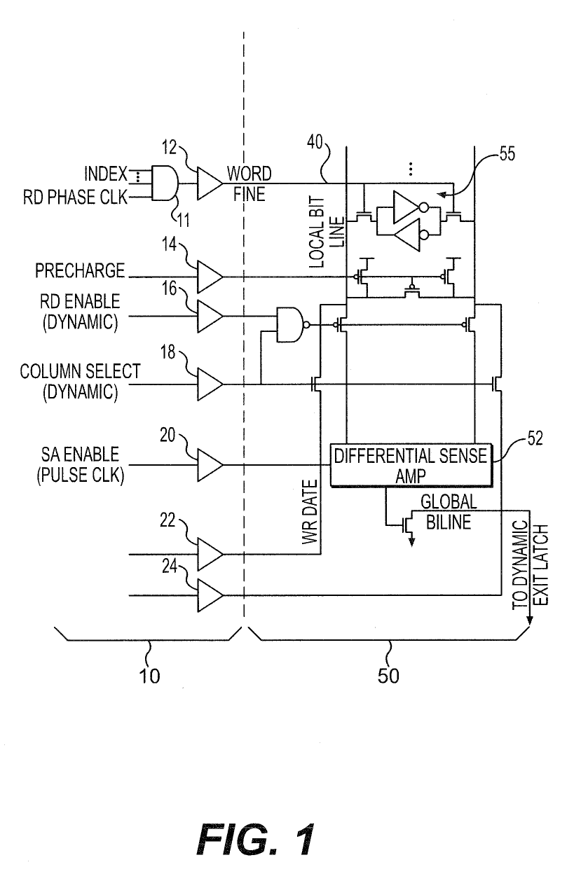

FIG. 1 shows a memory interface and a portion of a memory array according to an example arrangement. Other arrangements are also possible. More specifically, FIG. 1 shows a memory interface 10 that receives control signals (such as input signals and clock signals). The memory interface 10 may perform various decoder and clock generation operations.

FIG. 1 also shows one bitslice 50 (or column slice) of a plurality of bitslices that are provided within a memory (or cache). The memory may be a Static Random Access Memory (SRAM) array having a plurality of rows and a plurality of columns. For ease of illustration, FIG. 1 only shows one bitslice 50 (or column slice) and one memory cell 55 within the memory. Other cells may be provided within the same column as the cell 55, and other cells may be provided within the same row as the cell 55. As one example, the memory may include 128 memory cells. Each memory cell including the memory cell 55 may be formed of an inverter circuit, for example. Data may be written to the cell 55 or read from the cell 55 using word lines and bitlines. The bitslice 50 may also include a differential sense amplifier (amp) 52 to read signals from the memory cell 55. Components within the bitslice 50 (and other portions of the memory) may receive power from a single voltage supply.

The memory interface 10 may be provided at a boundary of the bitslice 50. The memory interface 10 may include a plurality of drivers 12, 14, 16, 18, 20, 22 and 24 to apply signals to the bitslice 50. Other circuit components, such as a logical AND gate 11 may also be provided within the memory interface 10. Components within the memory interface 10 may receive power from two voltage supplies, as will be described below.

As shown in FIG. 1, the AND gate 11 may receive an index signal and a read (RD) phase clock signal. The AND gate 11 may provide an output signal to the driver 12. The driver 12 may provide a word line signal along a signal line 40 to the memory cell 55 (and to other memory cells on the same row). The word line signal may be used to address the cell 55 (and the other cells on the same row).

Additionally, the driver 14 may receive a precharge signal (or PhaseCK signal) and provide an output to the bitslice 50. The driver 16 may receive a read (RD) enable signal and provide an output to the bitslice 50. The driver 18 may receive a column select signal and provide an output to the bitslice 50. The column select signal may be used to select a particular column of the memory array. Still further, the driver 20 may receive a sense amplifier (SA) enable signal and provide an output to the differential sense amplifier 52 in the bitslice 50.

Drivers 22 and 24 may also be provided about the boundary of the bitslice 50. Data may be written into the cell 55 (and other cells in the same column of the memory) using the drivers 22 and 24. Additionally, data may be read out of the cell (and the other cells in the column of the memory) using the driver 24.

The memory interface 10 may receive power from more than one voltage supply. For example, components within the memory interface 10 may be powered by a voltage from the voltage supply that is different than a voltage applied to the bitslice. Therefore, components within the memory (or the bitslice 50) may be powered by a different voltage source than some of the components within the memory interface 10. As one example, the drivers 12, 14, 16 and 18 that drive control signals into the bitslice 50 may perform a voltage conversion. More specifically, embodiments of the present invention may provide a voltage conversion at drivers from one voltage to another voltage. For example, the voltage conversion may be provided at the drivers 12, 14, 16 and 18 because the drivers are after a clock tree that controls timing of signals to the memory array.

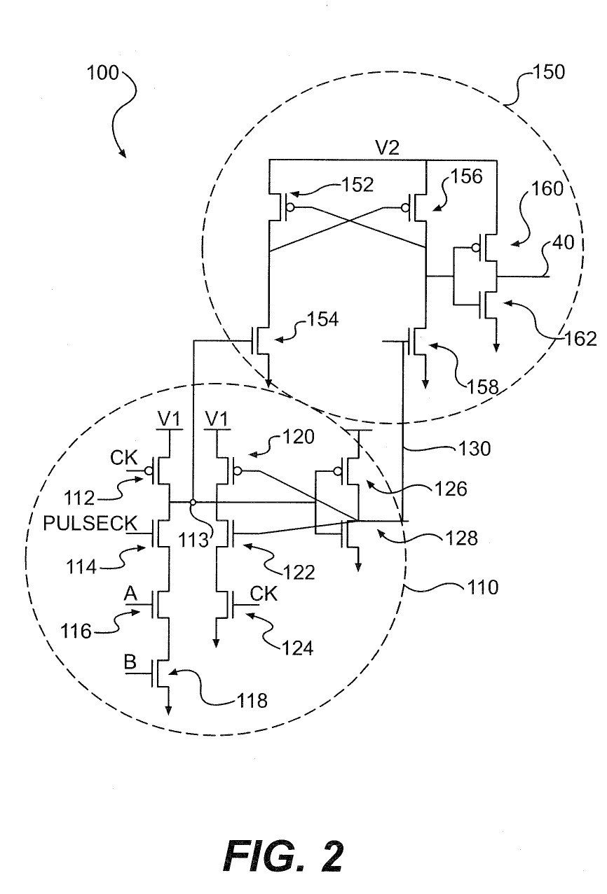

FIG. 2 shows a voltage converting driver apparatus 100 according to an example embodiment of the present invention. Other embodiments and configurations are also within the scope of the present invention. The voltage converting driver apparatus 100 may correspond to a word line driver, such as the driver 12 (and the AND gate 11) shown in FIG. 1 that provides the word line signal to the cell 55 (and other cells on the same row). However, the voltage converting driver apparatus 100 may also correspond to other drivers, such as the column select driver 18 or the drivers 14, 16 and 20. For ease of illustration, the voltage converting driver apparatus 100 of FIG. 2 will be described with respect to the driver 12 (i.e., the word line driver) shown in FIG. 1.

As shown in FIG. 2, the voltage converting driver apparatus 100 includes two voltage supplies V1 and V2. The voltage supply V1 may supply power of a first voltage and the voltage supply V2 may supply power of a second voltage that is different than the first voltage. The voltage converting driver apparatus 100 may provide a voltage conversion for the components of the memory array device (on the chip).

In this example, the voltage converting apparatus 100 is a dynamic word driver (or entry gate) to drive the word line (or the signal line 40) to the cell 55 in the memory (and other cells on the same row). The voltage converting apparatus 100 may include a dynamic driver circuit 110 and a voltage converting circuit 150. The dynamic driver circuit 110 may be coupled to the voltage converting circuit 150 by a signal line 130.

The dynamic driver circuit 110 may include transistors that receive power from a voltage supply V1. The dynamic driver circuit 110 may receive static logic and convert the received static logic into dynamic data (of a dynamic domain). The dynamic driver circuit 110 may receive a clock signal, input signals and receive power from voltage supply V1.

The voltage converting circuit 150 may include transistors that receive power from a voltage supply V2, which is a different voltage source than the voltage supply V1. The voltage converting circuit 150 may be considered a static circuit. The voltage converting circuit 150 may provide an output signal, such as a word line signal to be applied on the signal line 40 of FIG. 1 (for addressing the cell 55 within the memory).

The dynamic driver circuit 110 may include a first set of stacked transistors 112, 114, 116 and 118. The transistor 112 may be a p-channel metal-oxide-semiconductor (PMOS) transistor coupled to the voltage supply V1. The transistors 114, 116 and 118 may be n-channel metal-oxide-semiconductor (NMOS) transistors. The transistor 112 may receive the clock CK signal and the transistor 114 may receive the PulseCK signal. The transistors 116 and 118 may receive inputs A and B, respectively. In this dynamic circuit, when the clock CK signal is low, a dynamic signal provided on the signal line 130 may be driven low. On the other hand, when the clock CK signal CK is high, the inputs A, B are evaluated in manner of a dynamic circuit to provide a dynamic signal.

The dynamic driver circuit 110 also includes a second set of stacked transistors 120, 122 and 124 and a third set of stacked transistors 126 and 128. The transistors 120 and 126 may be PMOS transistors coupled to the voltage supply V1. The transistors 122, 124 and 128 may be NMOS transistors. Accordingly, each of the second set of stacked transistors 120, 122 and 124 and the third set of stacked transistors 126 and 128 may receive power from the voltage supply V1. Based on the input CK signal and the inputs A, B, the dynamic signal may be provided on the signal line 130 output from a node between the transistors 126, 128 (that act as an inverter). Stated differently, the dynamic driver circuit 110 may provide the dynamic signal based on the input CK signal and the input signals (such as the inputs A, B).

The PMOS transistor 112 coupled to the clock CK signal may be considered a pull-up transistor. The output of the dynamic driver circuit 110 may be preconditioned during one state (or phase) of the clock CK signal and evaluated during the other state (or phase) of the clock CK signal. The dynamic driver circuit 110 may operate in a precharge state (or phase) and an evaluate state (or phase) to provide the dynamic signal.

The dynamic driver circuit 110 may include full feedback holders to a node 113 with an evaluate clock providing a short pulse clock PulseCK signal to minimize a hold time and support a pulsed clock methodology. As one example, when the clock CK signal and the PulseCk signal are low, the dynamic driver circuit 10 is in a precharge (i.e., precondition) state and the signal line 130 (or node) is low. The evaluate state (or phase) may then start and both the clock CK signal and the PulseCK signal go high, and when the PulseCK signal goes high, the transistors 116, 118 (of the pull down stack) are enabled. If the inputs to the transistors 116, 118 both go high, the stack (of the transistors 116, 118) will turn on, the node 113 will be pulled down, and the full feedback will maintain that level on the node 113 until the dynamic driver circuit 110 reenters the precharge state (i.e., the clock CK signal goes low again). The PulseCK signal only stays high for a pulse long enough for the node 113 to evaluate and turn the feedback on. Once the PulseCK signal goes low, the dynamic driver circuit 110 maintains the state again until the clock CK signal goes low. When the PulseCK signal goes low, the evaluate stack is disabled thereby allowing the inputs to start changing again. Accordingly, a pulse clocked methodology provides an ability to propagate data from state to state with only one clock as compared to a two clock system.

The voltage converting circuit 150 may operate as a static voltage converting circuit and include a plurality of transistors 152, 154, 156, 158, 160 and 162. The transistors 152 and 154 may be provided in a stacked manner such that the transistor 152 is coupled to the voltage supply V2. The transistors 156 and 158 may also be provided in a stacked manner such that the transistor 156 is coupled to the voltage supply V2. Additionally, the transistors 160 and 162 may also be provided in a stacked manner such that the transistor 160 is coupled to the voltage supply V2. The transistors 152, 156 and 160 may be PMOS transistors and the transistors 154, 158 and 162 may be NMOS transistors.

A gate of the transistor 154 may be coupled to the node 113 of the dynamic driver circuit 110. A gate of the transistor 158 may be coupled to the signal line 130 to receive the dynamic signal from the dynamic driver circuit 110. The output signal of the voltage converting driver apparatus 100 (and the voltage converting circuit 150) may be provided on the signal line 40. This output signal may correspond to the word line signal shown in FIG. 1.

The dynamic driver circuit 110 may receive power from the voltage supply V1 and provide a dynamic signal on the signal line 130 based on the clock CK signal and the inputs A, B signals. On the other hand, the voltage converting circuit 150 may receive power from the voltage supply V2. The voltage converting circuit 150 may also receive the dynamic signal on the signal line 130 from the dynamic driver circuit 110 and provide an output signal (such as a word line signal) based on the received dynamic signal. The output signal may be provided to a memory cell of a memory array, for example.

The use of a voltage converting circuit is not limited to word line drivers for memory arrays. Voltage converting circuits may also be used with or as part of other types of drivers (for memory) such as for column drivers, sense amplifier enable drivers and global data drivers, for example.

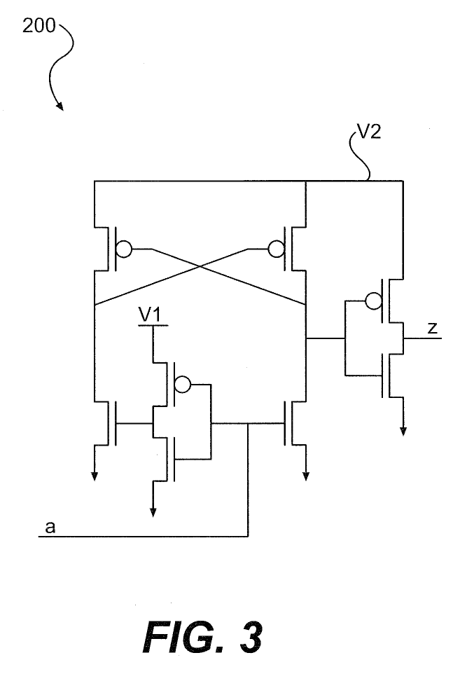

As one example, FIG. 3 shows a pulse signal voltage converting driver apparatus 200 that corresponds to the driver 20 shown in FIG. 1. The pulse signal voltage driver apparatus 200 within the memory array may receive a sense amplifier enable signal (a) and provide an output signal z to the differential sense amplifier 52 shown in FIG. 1. As shown, the pulse signal voltage converting driver apparatus 200 may be powered by both voltage supplies V1, V2. This type of voltage converting driver apparatus may be provided for phase based signals. For example, an output pulse width of the output signal z may be larger than an output pulse width of the enable signal a. This may help to provide that an adequate sense amplifier enable pulse is delivered to the differential sense amplifier 52 regardless of the voltage level shift between the memory interface 10 and the bitslice 50.

Voltage converting circuits may also be provided on (or within) global data drivers that drive write data in the memory array. The voltage converting circuits may provide an additional delay to the input signals.

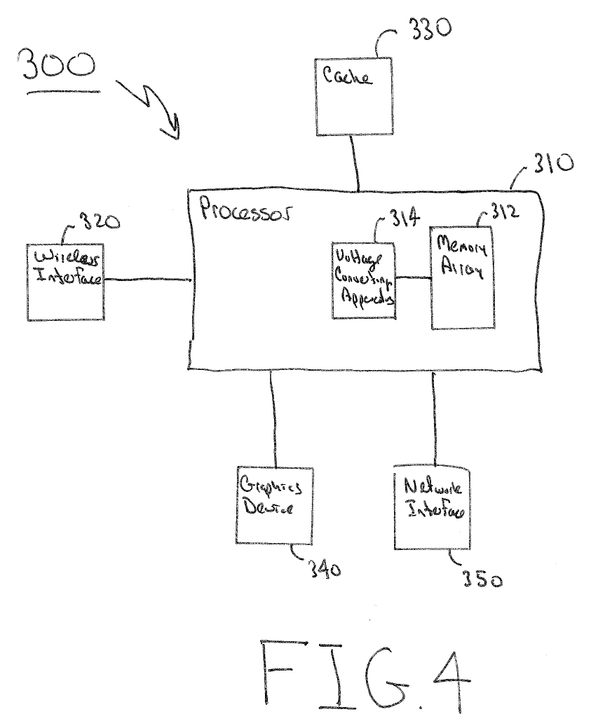

FIG. 4 shows an apparatus according to an example embodiment of the present invention. Other embodiments and configurations are also within the scope of the present invention. More specifically, FIG. 4 shows an apparatus 300 that includes a processor 310 having at least a memory array 312 and a voltage converting apparatus 314. The processor 310 may include elements not shown in FIG. 4. The processor 310 may process data within the apparatus 300. The processor 310 may be part of an integrated circuit that also includes at least one voltage supply. The memory array 312 may correspond to a SRAM memory array as discussed above. The voltage converting apparatus 314 may correspond to the voltage converting apparatus 100 as discussed above with respect to FIG. 2. The voltage converting apparatus 314 may provide signals to the memory array 312 and may obtain signals from the memory array 312.

The apparatus 300 may include components coupled to the processor 310 such as a wireless interface 320 and a memory (or cache) 330. A voltage converting apparatus similar to the voltage converting apparatus 100 of FIG. 2 may be associated with the memory 330 The wireless interface 320 may wirelessly interface with other apparatuses, devices, systems and/or networks. The processor 310 may also be coupled to a graphics device 340 (and/or display device) to display data and images, a network interface 350 and at least one power supply (or voltage supply (not shown). Other devices may also be coupled to the processor 310.

While the above embodiments have been described with respect to metal-oxide-semiconductor (MOS) transistors, embodiments may also include field-effect-transistors (FETs) rather than MOS transistors.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments of the present invention have been described with reference to a number of illustrative embodiments thereof, it should be understood that numerous other modifications and embodiments can be devised by those skilled in the art that will fall within the spirit and scope of the principles of this invention. More particularly, reasonable variations and modifications are possible in the component parts and/or arrangements of the subject combination arrangement within the scope of the foregoing disclosure, the drawings and the appended claims without departing from the spirit of the invention. In addition to variations and modifications in the component parts and/or arrangements, alternative uses will also be apparent to those skilled in the art.

1. An apparatus comprising:
a dynamic driver circuit to receive a clock signal, a pulse clock signal and input signals, the dynamic driver circuit to receive power from a first voltage supply, the dynamic driver circuit to provide a dynamic signal based on the clock signal and the input signals; and
a voltage converting circuit to receive the dynamic signal from the dynamic driver circuit, the voltage converting circuit to receive power from a second voltage supply, the voltage converting circuit to provide an output signal based on the received dynamic signal, and the dynamic driver circuit to operate in a precharge state, based on the received pulse clock signal and the received clock signal, and an evaluate state to provide the dynamic signal to the voltage converting circuit.

2. The apparatus of claim 1, wherein the dynamic driver circuit includes a plurality of transistors.

3. The apparatus of claim 2, wherein the plurality of transistors includes a first set of stacked transistors, a second set of stacked transistors and a third set of stacked transistors.

4. The apparatus of claim 3, wherein one transistor of the first set of stacked transistors coupled to the first voltage supply, one transistor of the second set of stacked transistors coupled to the first voltage supply and one transistor of the third set of stacked transistors coupled to the first voltage supply.

5. The apparatus of claim 4, wherein the third set of stacked transistors provides the dynamic signal to a signal line, and the voltage converting circuit couples to the signal line.

6. The apparatus of claim 1, further comprising a memory array.

7. The apparatus of claim 6, wherein the voltage converting circuit provides the output signal to a word line of the memory array.

8. (canceled)

9. The apparatus of claim 1, wherein the power from the first voltage supply is different than the power from the second voltage supply.

10. An apparatus comprising:
a wireless interface to wirelessly interface with another apparatus; and
a processor to process data within the apparatus, the processor including a memory array and a voltage converting apparatus, the voltage converting apparatus to provide signals to the memory array and to obtain signals from the memory array, the voltage converting apparatus including:
a driver circuit to receive static input signals a clock signal and a precharge signal, the driver circuit to provide a dynamic signal on a signal line based on the received static input signals, the received precharge signal and the received clock signal, the driver circuit including a plurality of transistors, the driver circuit to receive a first voltage from a first voltage supply, the driver circuit to operate in a precharge state based on the received clock signal and the received precharge signal, and the driver circuit to operate in an evaluate state to provide the dynamic signal on the signal line; and
a voltage converting circuit to couple to the signal line and to receive the dynamic signal from the driver circuit, the voltage converting circuit to receive a second voltage from a second voltage supply and the voltage converting circuit to provide a word line signal based on the received dynamic signal, the second voltage being different than the first voltage.

11. The apparatus of claim 10, further comprising a cache coupled to the processor. 12. The apparatus of claim 10, further comprising a graphics device to display data and images.

13. The apparatus of claim 10, wherein the plurality of transistors of the driver circuit includes a first set of stacked transistors, a second set of stacked transistors and a third set of stacked transistors, and one transistor of the first set of stacked transistors couples to the first voltage supply, one transistor of the second set of stacked transistors couples to the first voltage supply and one transistor of the third set of stacked transistors couples to the first voltage supply.

14. The apparatus of claim 13, wherein the signal line couples between the third set of stacked transistors and the voltage converting circuit.

15. (canceled)

16. The apparatus of claim 10, wherein the driver circuit to operate in the evaluate state when the clock signal and the precharge signal are both HIGH.

17. The apparatus of claim 10, wherein an output of the driver circuit is preconditioned during one state of the clock signal and is evaluated during the other state of the clock signal.

18. The apparatus of claim 10, wherein when the clock signal is HIGH, the input signals are evaluated to provide the dynamic signal.

19. The apparatus of claim 1, wherein the dynamic driver circuit to operate in the evaluate state when the clock signal and the pulse clock signal are both HIGH.

20. The apparatus of claim 1, wherein an output of the dynamic driver circuit is preconditioned during one state of the clock signal and is evaluated during the other state of the clock signal.

21. The apparatus of claim 1, wherein when the clock signal is HIGH, the input signals are evaluated to provide the dynamic signal.
